(19) United States
(12) Patent Application Publication
(10) Pub. No.: US 2016/0141493 A1
(43) Pub. Date: May 19, 2016

(54) NONVOLATILE MEMORY DEVICE

(71) Applicant: Kabushiki Kaisha Toshiba, Minato-ku (JP)

(72) Inventors: Harumi SEKI, Yokkaichi (JP); Takayuki ISHIKAWA, Yokkaichi (JP); Shosuke FUJII, Kuwana (JP); Masumi SAITOH, Yokkaichi (JP)

(73) Assignee: Kabushiki Kaisha Toshiba, Minato-ku (JP)

(21) Appl. No.: 14/944,568

(22) Filed: Nov. 18, 2015

(30) Foreign Application Priority Data
Nov. 19, 2014 (JP) 2014-234951

(51) Int. Cl. H01L 45/00

(52) U.S. Cl. CPC H01L 45/085; H01L 45/1233; H01L 45/1266; H01L 45/145

(57) ABSTRACT

According to one embodiment, a nonvolatile memory device includes a first metal layer, a second metal layer, a first layer, a second layer, and a third layer. The first metal layer contains at least one first metal selected from the group consisting of Al, Ni, Ti, Co, Mg, Cr, Mn, Zn, and In. The second metal layer contains at least one second metal selected from the group consisting of Ag, Cu, Fe, Sn, Pb, and Bi. The first layer is provided between the first metal layer and the second metal layer, and contains a first oxide. The second layer is provided between the first layer and the second metal layer, and contains a second oxide. The third layer is provided between the first layer and the second layer, and contains one of a silicon oxide, a silicon nitride, and a silicon oxynitride.

### CROSS-REFERENCE TO RELATED APPLICATIONS

This application is based upon and claims the benefit of priority from Japanese Patent Application No. 2014-234951, filed on Nov. 19, 2014; the entire contents of which are incorporated herein by reference.

### FIELD

Embodiments described herein relate generally to a nonvolatile memory device.

### BACKGROUND

As a nonvolatile memory device, there is a cross-point type resistance variable memory. In such a nonvolatile memory device, a sneak current may occur during operation, and thus, the operation may become unstable.

### BRIEF DESCRIPTION OF THE DRAWINGS

FIG. 1 is a schematic cross-sectional view showing a nonvolatile memory device according to a first embodiment;

FIG. 2A to FIG. 2F are schematic views showing operations of the nonvolatile memory device according to the first embodiment;

FIG. 3 is a schematic view showing characteristics of the nonvolatile memory device according to the first embodiment;

FIG. 4A to FIG. 4D are schematic perspective views illustrating a nonvolatile memory device according to a second embodiment;

FIG. 5 is a schematic plan view showing the nonvolatile memory device according to the second embodiment; and

FIG. 6 is a schematic cross-sectional view showing another nonvolatile memory device according to the second embodiment.

### DETAILED DESCRIPTION

According to one embodiment, a nonvolatile memory device includes a first metal layer, a second metal layer, a first layer, a second layer, and a third layer. The first metal layer contains at least one first metal selected from the group consisting of Al, Ni, Ti, Co, Mg, Cr, Mn, Zn, and In. The second metal layer contains at least one second metal selected from the group consisting of Ag, Cu, Fe, Sn, Pb, and Bi. The first layer is provided between the first metal layer and the second metal layer, and contains a first oxide. The second layer is provided between the first layer and the second metal layer, and contains a second oxide. The third layer is provided between the first layer and the second layer, and contains one of a silicon oxide, a silicon nitride, and a silicon oxynitride.

According to another embodiment, a nonvolatile memory device includes a first metal layer, a second metal layer, a first layer, a second layer, and a third layer. The first metal layer contains at least one first metal selected from the group consisting of Ti, Co, and Cr. The second metal layer contains at least one second metal selected from the group consisting of Ag, Cu, Al, Ni, Mg, Mn, Fe, Zn, Sn, In, Pb, and Bi. The first layer is provided between the first metal layer and the second metal layer, and contains silicon. The second layer is provided between the first layer and the second metal layer, and contains silicon. The third layer is provided between the first layer and the second layer, and contains one of a silicon oxide, a silicon nitride, and a silicon oxynitride.

According to another embodiment, a nonvolatile memory device includes a first metal layer, a second metal layer, a first layer, a second layer, and a third layer. The first metal layer contains at least one first metal selected from the group consisting of Ti, Co, and Cr. The second metal layer contains at least one second metal selected from the group consisting of Ag, Cu, Fe, Sn, Pb, and Bi. The first layer is provided between the first metal layer and the second metal layer, and contains silicon. The second layer is provided between the first layer and the second metal layer, and contains a second oxide. The third layer is provided between the first layer and the second layer, and contains one of a silicon oxide, a silicon nitride, and a silicon oxynitride. According to another embodiment, a nonvolatile memory device includes a first metal layer, a second metal layer, a first layer, a second layer, and a third layer. The first metal layer contains at least one first metal selected from the group consisting of Al, Ni, Ti, Co, Mg, Cr, Mn, Zn, and In. The second metal layer contains at least one second metal selected from the group consisting of Ag, Cu, Al, Ni, Mg, Mn, Fe, Zn, Sn, In, Pb, and Bi. The first layer is provided between the first metal layer and the second metal layer, and contains a first oxide. The second layer is provided between the first layer and the second metal layer, and contains silicon. The third layer is provided between the first layer and the second layer, and contains one of a silicon oxide, a silicon nitride, and a silicon oxynitride.

According to another embodiment, a nonvolatile memory device includes a first metal layer, a second metal layer, a first layer, a second layer, and a third layer. The first metal layer contains at least one first metal selected from the group consisting of Ag, Cu, Al, Ni, Ti, Co, Mg, Cr, Mn, Fe, Zn, Sn, In, Pb, and Bi. The second metal layer contains at least one second metal selected from the group consisting of Ag, Cu, Al, Ni, Ti, Co, Mg, Cr, Mn, Fe, Zn, Sn, In, Pb, and Bi, and the second metal is different from the first metal. The first layer is provided between the first metal layer and the second metal layer, and contains a first material of one of a first oxide and silicon. The second layer is provided between the first layer and the second metal layer, and contains a second material of one of a second oxide and silicon. The third layer is provided between the first layer and the second layer, and contains one of a silicon oxide, a silicon nitride, and a silicon oxynitride. Binding energy between the first metal and oxygen is higher than binding energy between the second metal and oxygen when the first material includes the first oxide and the second material includes the second oxide. The binding energy between the first metal and oxygen is higher than binding energy between the second metal and silicon when the first material includes the first oxide and the second material includes silicon. Binding energy between the first metal and silicon is higher than the binding energy between the second metal and oxygen when the first material includes silicon and the second material includes the second oxide. The binding energy between the first metal and silicon is higher than the binding energy between the second metal and silicon when the first material includes silicon and the second material includes silicon.

According to another embodiment, a nonvolatile memory device includes a first metal layer, a second metal layer, a first layer, a second layer, a third layer, and a control circuit. The first metal layer contains a first metal. The second metal layer contains a second metal, and the second metal is different from the first metal. The first layer is provided between the first metal layer and the second metal layer, and contains one of a first oxide and silicon. The second layer is provided between the first layer and the second metal layer, and contains one of a second oxide and silicon. The third layer is provided between the first layer and the second layer, and contains one of a silicon oxide, a silicon nitride, and a silicon oxynitride. The control circuit is configured to apply a first potential and a second potential to the first metal layer. A first current path is formed in the first layer when the control circuit performs a first operation of applying the first potential to the first metal layer. The first potential is positive with respect to the second metal layer. A second current path is formed in the second layer when the control circuit performs a second operation of applying the second potential to the first metal layer. The second potential is negative with respect to the second metal layer. A second time period when the second current path continues to exist after completion of the application of the second potential is shorter than a first time period when the first current path continues to exist after completion of the application of the first potential.

Various embodiments will be described hereinafter with reference to the accompanying drawings.

In addition, the drawings are illustrated schematically or conceptually, and relations between thicknesses and widths of the respective portions and ratios of sizes between the portions may not be necessarily shown as actual dimensions. Further, even in a case where the same portions are shown, the dimensions or the ratios thereof may be shown differently from each other depending on the drawings.

In addition, in the specification and the drawings of the application, the same elements as those in a previously mentioned description relating to a previous drawing will be denoted with the same symbols and the detailed description thereof will appropriately not be made.

### First Embodiment

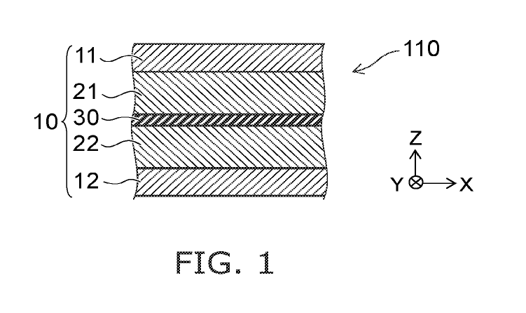

FIG. 1 is a schematic cross-sectional view illustrating a nonvolatile memory device according to a first embodiment.

As illustrated in FIG. 1, the nonvolatile memory device 110 according to the embodiment includes a stacked body 10. The stacked body 10 includes a first metal layer 11, a second metal layer 12, a first layer 21, a second layer 22, and a third layer 30.

The first layer 21 is provided between the first metal layer 11 and the second metal layer 12. The second layer 22 is provided between the first layer 21 and the second metal layer 12. The third layer 30 is provided between the first layer 21 and the second layer 22. In the example, the first layer 21 is in contact with the first metal layer 11 and is in contact with the third layer 30. The second layer 22 is in contact with the second metal layer 12 and the third layer 30.

A stacking direction from the second layer 22 toward the first layer 21 will be assumed as a Z-axis direction. A direction perpendicular to the Z-axis direction will be assumed as an X-axis direction. A direction perpendicular to the Z-axis direction and the X-axis direction will be assumed as a Y-axis direction.

The first metal layer 11 is separated from the second metal layer 12 in the Z-axis direction. For the first metal layer 11 and the second metal layer 12, a metal which is easy to ionize is used.

For example, the first metal layer 11 contains a first metal. The first metal includes at least one selected from the group consisting of Ag, Cu, Al, Ni, Ti, Co, Mg, Cr, Mn, Fe, Zn, Sn, In, Pb, and Bi.

For example, the second metal layer 12 contains a second metal. The second metal includes at least one selected from the group consisting of Ag, Cu, Al, Ni, Ti, Co, Mg, Cr, Mn, Fe, Zn, Sn, In, Pb, and Bi.

The first layer 21 contains a first material. The first material is one of a first oxide and silicon.

The second layer 22 contains a second material. The second material is one of a second oxide and silicon. The second oxide may be the same as or different from the first oxide.

The first layer 21 is, for example, a first resistance variable layer. For example, according to a voltage applied to the first layer 21, electric resistance of the first layer 21 is transitioned between a state (low resistance state) where the resistance is low and a state (high resistance state) where the resistance is higher than that of the low resistance state.

The second layer 22 is, for example, a second resistance variable layer. For example, according to a voltage applied to the second layer 22, electric resistance of the second layer 22 is transitioned between a state (low resistance state) where the resistance is low and a state (high resistance state) where the resistance is higher than that of the low resistance state.

The third layer 30 contains one of a silicon oxide, a silicon nitride, and a silicon oxynitride. The third layer 30 suppresses diffusion of metal elements, for example, between the first layer 21 and the second layer 22.

As described below, by applying a voltage between the first metal layer 11 and the second metal layer 12, respective current paths (filaments) are formed, for example, in the first layer 21 and the second layer 22. Thereby, electric resistance of the stacked body 10 is varied.

In the embodiment, for example, binding energy between the first metal of the first metal layer 11 and an element contained in the first layer 21 is set to be higher than binding energy between the second metal of the second metal layer 12 and an element contained in the second layer 22. Thereby, stability of the filament formed in the first layer 21 becomes higher than the stability of the filament formed in the second layer 22.

For example, in the case where the first material of the first layer 21 includes a first oxide and the second material of the second layer 22 includes a second oxide, the binding energy between the first metal of the first metal layer 11 and oxygen is set to be higher than the binding energy between the second metal of the second metal layer 12 and oxygen.

For example, in the case where the first material includes the first oxide and the second material includes silicon, the binding energy between the first metal and oxygen is set to be higher than the binding energy (binding energy of silicide) between the second metal and silicon.

For example, in the case where the first material includes silicon and the second material includes the second oxide, the binding energy (binding energy of silicide) between the first metal and silicon is set to be higher than the binding energy between the second metal and oxygen.

For example, in the case where the first material includes silicon and the second material includes silicon, the binding energy between the first metal and silicon is set to be higher than the binding energy between the second metal and silicon.

Thereby, the filament formed in the second layer 22 disappears within a relatively short time. On the other hand, the filament formed in the first layer 21 continues to exist for a long time. In other words, the electric resistance state (low resistance state) of the first layer 21 continues to be stable for a long time. The electric resistance state (low resistance state) of the second layer 22 disappears within a short time.

For example, in the case where the first material of the first layer 21 includes the first oxide and the second material of the second layer 22 includes the second oxide (first configuration), the first metal of the first metal layer 11 is selected from the group consisting of Al, Ni, Ti, Co, Mg, Cr, Mn, Zn, and In, and the second metal of the second metal layer 12 is selected from the group consisting of Ag, Cu, Fe, Sn, Pb, and Bi.

For example, in the case where the first material includes silicon and the second material includes silicon (second configuration), the first metal of the first metal layer 11 is selected from the group consisting of Ti, Co, and Cr, and the second metal of the second metal layer 12 is selected from the group consisting of Ag, Cu, Al, Ni, Mg, Mn, Fe, Zn, Sn, In, Pb, and Bi.

For example, in the case where the first material includes the first oxide and the second material includes silicon (third configuration), the first metal of the first metal layer 11 is selected from the group consisting of Al, Ni, Ti, Co, Mg, Cr, Mn, Zn, and In, and the second metal of the second metal layer 12 is selected from the group consisting of Ag, Cu, Al, Ni, Mg, Mn, Fe, Zn, Sn, In, Pb, and Bi.

For example, in the case where the first material includes silicon and the second material includes the second oxide (fourth configuration), the first metal of the first metal layer 11 is selected from the group consisting of Ti, Co, and Cr, and the second metal of the second metal layer 12 is selected from the group consisting of Ag, Cu, Fe, Sn, Pb, and Bi.

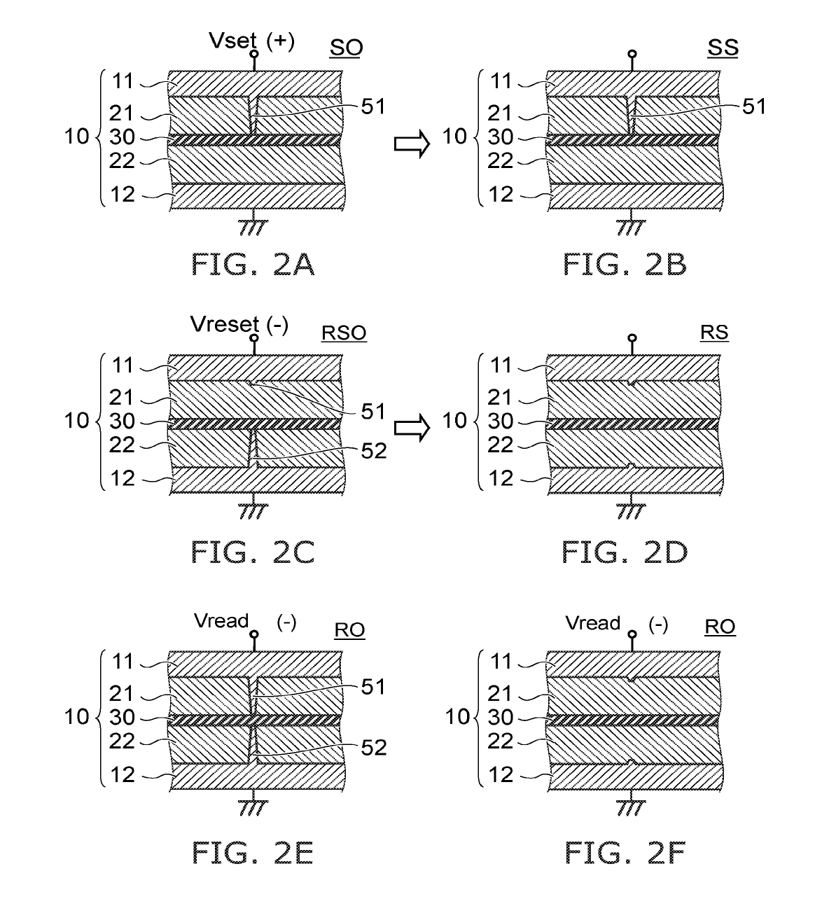

FIG. 2A to FIG. 2F are schematic views illustrating operations of the nonvolatile memory device according to the first embodiment.

FIG. 2A and FIG. 2B illustrate a set operation SO. FIG. 2C and FIG. 2D illustrate a reset operation RSO. FIG. 2E and FIG. 2F illustrate a read operation RO.

As shown in FIG. 2A, a first pulse (Vset voltage pulse, a first voltage, a first potential) which is positive with respect to the second metal layer 12 is applied to the first metal layer 11. This operation corresponds to the set operation SO (first operation). The first metal contained in the first metal layer 11 is easy to ionize. The first metal is ionized, and the ionized first metal is moved in the first layer 21 by an electric field formed by the first pulse. In other words, a portion of the first metal (for example, Ni) contained in the first metal layer 11 is moved (for example, diffused) in the first layer 21. The filament of the first metal is formed in the first layer 21. The filament (first current path 51) extends from the first metal layer 11 toward the third layer 30 and reaches, for example, the third layer 30. Thereby, the first current path 51 (filament) is formed in the first layer 21. The diffusion of the first metal is suppressed by the third layer 30. Thereby, the first current path 51 does not substantially infiltrate into the second layer 22.

As shown in FIG. 2B, even after the first pulse is removed, the first current path 51 continues to exist. In other words, a retention time of the first current path 51 is long. The first current path 51 is formed in the first layer 21 by the set operation SO. Thereby, the stacked body 10 becomes a set state SS (low resistance state).

As shown in FIG. 2C, a second pulse (Vreset voltage pulse, a second voltage, a second potential) which is negative with respect to the second metal layer 12 is applied to the first metal layer 11. For example, the first metal layer 11 is set to a ground potential, and a positive voltage may be applied to the second metal layer 12. This operation corresponds to the reset operation RSO (second operation). Due to the second pulse, the first metal in the first layer 21 returns to the first metal layer 11. Thereby, the first current path 51 formed in the first layer 21 is separated from the third layer 30. Alternatively, it substantially disappears.

On the other hand, the second metal contained in the second metal layer 12 is easy to ionize. The second metal is ionized, and the ionized second metal is moved in the second layer 22 by an electric field formed by the second pulse. In other words, a portion of the second metal (for example, Cu) contained in the second metal layer 12 is moved (for example, diffused) in the second layer 22 by the second pulse. The filament of the second metal is formed in the second layer 22. The filament (second current path 52) extends from the second metal layer 12 toward the third layer 30 and reaches, for example, the third layer 30. Thereby, second current path 52 (filament) is formed in the second layer 22. The diffusion of the second metal is suppressed by the third layer 30. Thereby, the second current path 52 does not substantially infiltrate into the first layer 21.

The binding energy between the second metal and an element (oxygen or silicon) contained in the second layer 22 is set to be low. Therefore, the filament formed of the second metal is easy to remove. A second time period when the second current path 52 continues to exist after completion of the application of the second pulse is shorter than a first time period when the first current path 51 continues to exist after completion of the application of the first pulse.

Therefore, as shown in FIG. 2D, immediately after the second pulse is removed, the second current path 52 is separated from the third layer 30. The second current path 52, for example, substantially disappears. In other words, the retention time of the second current path 52 is short. Thereby, the stacked body 10 becomes a reset state RS (high resistance state).

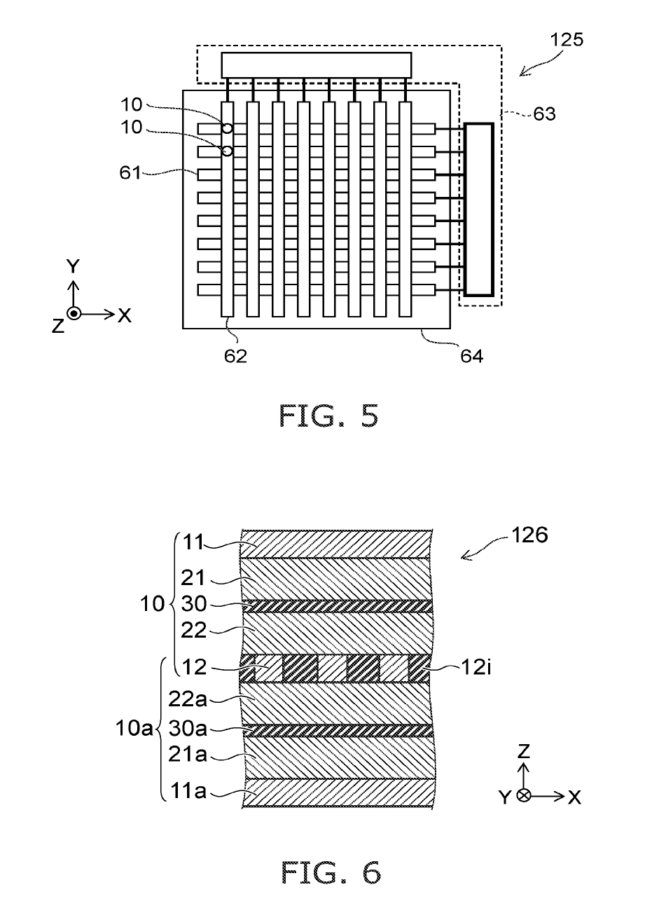

FIG. 2E illustrates a read operation RO when the stacked body 10 is in the set state SS. A third voltage (Vread voltage, a third potential) which is negative with respect to the second metal layer 12 is applied to the first metal layer 11. An absolute value of the third voltage is smaller than the absolute value of the voltage (second voltage) of the second pulse. The third voltage is set as a value which does not substantially change the first current path 51 formed in the first layer 21. By applying the third voltage, the second current path 52 is formed in the second layer 22. In this state, the electric resistance between the first metal layer 11 and the second metal layer 12 is detected. The electric resistance is low. For example a control circuit (for example, a control unit 63 shown in FIG. 5) detects the electric resistance between the first metal layer 11 and the second metal layer 12.

On the other hand, FIG. 2F illustrates the read operation RO when the stacked body 10 is in the reset state RS. In this case, the third voltage (Vread voltage) which is negative with respect to the second metal layer 12 is also applied to the first metal layer 11. Since the absolute value of the third voltage is small, the second current path 52 is not substantially formed in the second layer 22. In this state, the electric resistance between the first metal layer 11 and the second metal layer 12 is detected. The electric resistance is high. In other words, the electric resistance when the stacked body 10 is in the reset state RS is higher than the electric resistance when the stacked body 10 is in the set state SS.

After the first voltage (first pulse, Vset voltage) which is positive with respect to the second metal layer 12 is applied to the first metal layer 11, the electric resistance between the first metal layer 11 and the second metal layer 12 is first resistance which is in the low resistance state. In other words, the set state SS is formed. For example the control circuit (for example, a control unit 63 shown in FIG. 5) applies the first potential (voltage) to the first metal layer 11.

After the second voltage (second pulse, Vreset voltage) which is negative with respect to the second metal layer 12 is applied to the first metal layer 11, the electric resistance between the first metal layer 11 and the second metal layer 12 is second resistance which is in the high resistance state. The second resistance is higher than the first resistance. In other words, the reset state RS is formed. For example a control circuit (for example, a control unit 63 shown in FIG. 5) applies the second potential (voltage) to the first metal layer 11.

Next, by applying the third voltage (Vread voltage) which is negative with respect to the second metal layer 12 and of which absolute value is smaller than that of the second voltage to the first metal layer 11, the electric resistance of the stacked body 10 (electric resistance between the first metal layer 11 and the second metal layer 12) is detected.

The set state SS is set to correspond to, for example, a “1” state. The reset state RS is set to correspond to, for example, a “0” state. By using these states, information can be stored in the stacked body 10 in the nonvolatile memory device 110. In the embodiment, a relationship between a combination of the set state SS and the reset state RS and a combination of the “1” state and the “0” state may be reverse.

As described with reference to FIG. 2B and FIG. 2D, after completion of the application of the voltage pulse, the second current path 52 does not substantially exist in the second layer 22. Therefore, in both of the set state SS and the reset state RS, the second layer 22 is in the high resistance state.

Thereby, even in the case where an unintended voltage (for example, a voltage causing a sneak current) is applied to the stacked body 10, the state can be maintained stable. The second layer 22 may be considered to have, for example, a rectifying function.

The stacked body 10 is applied to, for example, a cross-point type memory. In the stacked body 10, a write operation (set operation SO), a read operation RO, and an erase operation (reset operation RSO) are performed. In this case, the sneak current may occur. In the embodiment, the influence of the sneak current is suppressed, and thus, the operations can be stably performed. According to the embodiment, it is possible to provide a nonvolatile memory device capable of stably performing operations.

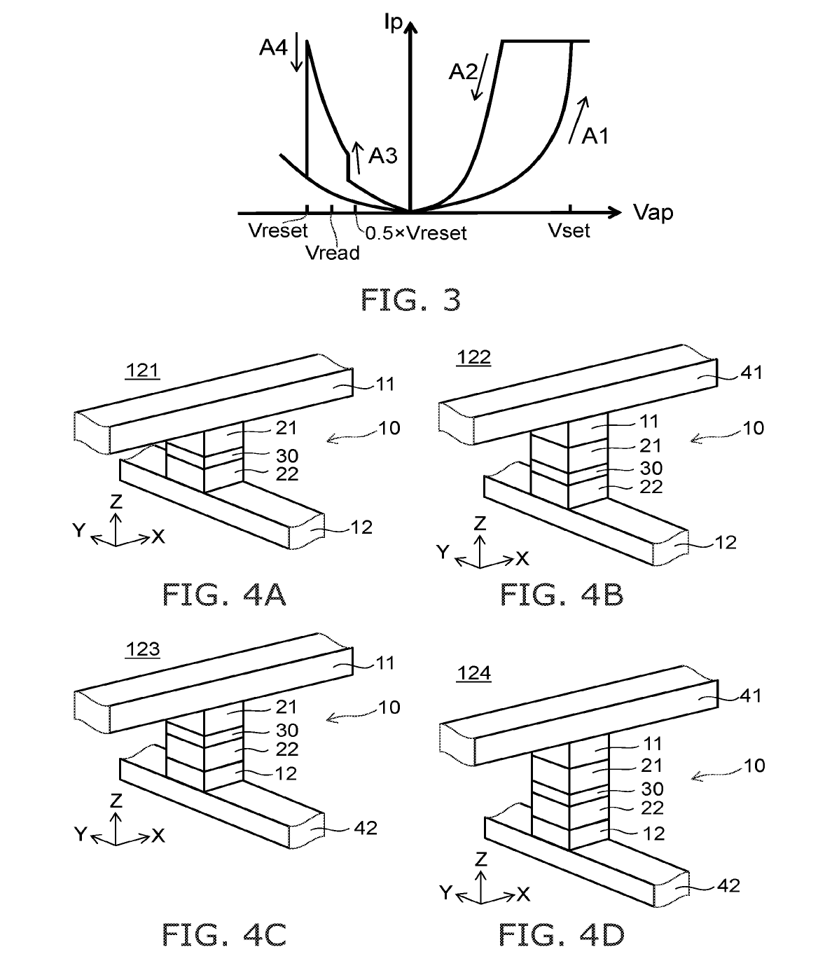

FIG. 3 is a schematic view illustrating characteristics of the nonvolatile memory device according to the first embodiment.

In FIG. 3, the horizontal axis denotes an applied voltage Vap applied between the first metal layer 11 and the second metal layer 12. The vertical axis denotes a current Ip flowing between the first metal layer 11 and the second metal layer 12. The applied voltage Vap is defined with respect to the second metal layer 12. The Vset voltage is positive, and the Vreset voltage and the Vread voltage are negative. A current flows from a conductor having a positive voltage (potential) to a conductor having a negative voltage (potential).

If the Vset voltage is applied (arrow A1), the low resistance state (set state SS) occurs. This corresponds to the write operation. If the applied voltage Vap is decreased (arrow A2) and the applied voltage Vap becomes negative, the stacked body 10 (second layer 22) is changed to the low resistance state (arrow A3). In this case, reading of the low resistance state can be performed. In addition, if the applied voltage Vap is decreased (absolute value of a negative voltage is increased), the state is transitioned to the high resistance state (reset state RS) (arrow A4). Thereby, the low resistance state is erased.

The read voltage Vread is set between a voltage (Vset voltage) where the state is transitioned to the low resistance state and a voltage (Vreset voltage) where the state is transitioned to the high resistance state. If the read voltage Vread is removed, the second layer 22 spontaneously returns to the high resistance state. Thereby, the stacked body 10 becomes the high resistance state.

In the embodiment, during the write operation, the read operation, and the erase operation, a leak current (sneak current) occurring in a non-selected cell caused by the current sneaking can be reduced. For example, favorably, the voltage where the change of arrow A3 (the second layer 22 is changed to the low resistance state) occurs has a value between 0.5×Vreset and Vread. Thereby, for example, in the case where a half of the reset voltage is applied to the non-selected cell (so-called a half-selected state), the sneak current can be suppressed.

In the embodiment, the second current path 52 formed in the second layer 22 is derived from the second metal contained in the second metal layer 12. The second current path 52 based on the second metal can be controlled according to the applied voltage. Favorably, the second oxide contained in the second layer 22 does not include a metal element other than the metal element bound with the oxygen of the second oxide. Thereby, controllability of the second current path 52 is increased. In the case where the second oxide contained in the second layer 22 is a hafnium oxide, favorably, the second oxide does not include another metal element except for the hafnium. In the case where the second oxide contained in the second layer 22 is an aluminum oxide, favorably, the second oxide does not include another metal element except for the aluminum. In the case where the second oxide contained in the second layer 22 is a titanium oxide, favorably, the second oxide does not include another metal element except for the titanium. Similarly, as described below, in the case where the second oxide contained in the second layer 22 is a zirconium oxide, a tantalum oxide, or an iron oxide, favorably, the second oxide does not include another metal element except for the zirconium, the tantalum, or the iron, respectively. The concentration of another metal in the second oxide is, for example, 5% or less. The concentration may also be less than 1%.

In the case where silicon (for example, polysilicon or the like) is used for the second layer 22, favorably, the second layer 22 does not contain a metal element. Thereby, controllability of the second current path 52 is increased. The concentration of the metal element in the second layer 22 is, for example, 5% or less. The concentration may also be less than 1%.

Favorably, the first oxide contained in the first layer 21 does not include a metal element other than the metal element bound with the oxygen of the first oxide. Thereby, controllability of the first current path 51 is increased. In the case where the first oxide is a hafnium oxide, favorably, the first oxide does not contain another metal element except for the hafnium. In the case where the first oxide contained in the first layer 21 is an aluminum oxide, favorably, the first oxide does not contain another metal element except for the aluminum. In the case where the first oxide contained in the first layer 21 is a titanium oxide, favorably, the first oxide does not contain another metal element except for the titanium. Similarly, as described below, in the case where the first oxide contained in the first layer 21 is a zirconium oxide, a tantalum oxide, or an iron oxide, favorably, the first oxide does not contain another metal element except for the zirconium, the tantalum, or the iron, respectively. The concentration of another metal in the first oxide is, for example, 5% or less. The concentration may also be less than 1%.

In the embodiment, after completion of the application of the second pulse, a second time period when the second current path 52 continues to exist is, for example, 100 microseconds or less. If the second time period is short, the speed of the operation becomes high.

In the embodiment, for example, the first oxide of the first layer 21 may be different from the second oxide of the second layer 22. For example, an aluminum oxide is used for the first layer 21, and for example, a hafnium oxide is used for the second layer 22. In this case, for example, Ni is used for the first metal layer 11, and Ag is used for the second metal layer 12.

In the embodiment, the first oxide of the first layer 21 may be the same as the second oxide of the second layer 22. For example, a silicon oxide is used for the first layer 21 and the second layer 22. In this case, for example, Ni is used for the first metal layer 11, and Cu is used for the second metal layer 12. In this case, the retention characteristic of the first layer 21 is higher than the retention characteristic of the second layer 22.

In the embodiment, for example, silicon (for example, polysilicon) may be used for the first layer 21, and silicon (for example, polysilicon) may be used for the second layer 22. In this case, for example, Ni is used for the first metal layer 11, and Ag is used for the second metal layer 12.

In the embodiment, silicon (for example, polysilicon) may be used for the first layer 21, and the second oxide (for example, a hafnium oxide) may be used for the second layer 22. In this case, for example, Ni is used for the first metal layer 11, and Ag is used for the second metal layer 12.

In the embodiment, the first oxide (for example, aluminum oxide) may be used for the first layer 21, and silicon (for example, polysilicon) may be used for the second layer 22. In this case, for example, Ni is used for the first metal layer 11, and Ag is used for the second metal layer 12.

By using one of a silicon oxide, a silicon nitride, and a silicon oxynitride for the third layer 30, it is possible to effectively suppress the diffusion of the metal element between the first layer 21 and the second layer 22.

Favorably, the thickness of the third layer 30 is 1 nm or more and 5 nm or less. If the thickness of the third layer 30 is less than 1 nm, for example, the diffusion of metal may be insufficiently suppressed. If the thickness of the third layer 30 is more than 5 nm, for example, the operating voltage is excessively increased.

Favorably, the thickness of the second layer 22 is 10 nm or less. If the thickness of the first layer 21 is more than 10 nm, for example, the operating voltage is excessively increased.

Favorably, the thickness of the second layer 22 is 10 nm or less. If the thickness of the second layer 22 is more than 10 nm, for example, the operating voltage is excessively increased.

The nonvolatile memory device 110 according to the embodiment is, for example, a resistance variable type memory. In the nonvolatile memory device 110, for example, a memory retention characteristic and a rectifying operation are compatible with each other.

By applying a cross-point type memory structure, a mass memory device can be realized. In the cross-point type memory structure, during the write operation, the read operation, and the erase operation, a current sneaks into the non-selected cell. In other words, the sneak current occurs. Due to the sneak current, the operations become unstable. In addition, power consumption is increased.

In order to solve the problem, there is a method of allowing a resistance variable memory element to have a rectifying function. However, if a rectifying element such as a diode is provided, the size of device is increased. Therefore, it is difficult to realize a mass storage device.

In order to realize a mass storage device, it is favorable that the device is allowed to have a long-time data retention characteristic. A novel structure having a high retention characteristic and a rectifying function is desired.

In the embodiment, the influence of the sneak current can be suppressed. Accordingly, the data retention characteristic is good.

In the nonvolatile memory device 110 according to the embodiment, a combination of the first metal layer 11 and the first layer 21 is set as a configuration where the retention characteristic is good. In other words, after the write pulse, the filament in the first layer 21 remains, and the first layer 21 maintains the low resistance state.

On the other hand, a combination of the second metal layer 12 and the second layer 22 is set as a configuration where the retention characteristic is bad. In other words, after an erase pulse or a read pulse, the second layer 22 is spontaneously transitioned to the high resistance state. Such a difference in retention characteristic can be obtained by a combination of an electrode and a resistance variable layer.

In the nonvolatile memory device 110, the first layer 21 functions as an information storage layer. The first layer 21 stores the high resistance state (for example, an erased state, for example, a “0” state) and the low resistance state (a written state, for example, a “1” state). On the other hand, the second layer 22 functions as a sneak current suppressing layer during the write operation, the read operation, and the erase operation. For example, the second layer 22 suppresses the sneak current occurring in the non-selected cell caused by the current sneaking. The stacked body 10 (memory element) includes a component (first layer 21) having a good data retention characteristic and a sneak current suppressing component (second layer 22) having a bad retention characteristic.

When the stacked body 10 of the nonvolatile memory device 110 stores the “0” state, the first layer 21 is in the high resistance state, and the second layer 22 is in the high resistance state. When the stacked body 10 stores “1”, the first layer 21 is in the low resistance state, and the second layer 22 is in the high resistance state. The “0” state and the “1” state stored by the stacked body 10 are distinguished according to a difference as to whether the first layer 21 is in the high resistance state or in the low resistance state. In the case where the stacked body 10 is in the “0” state or in the “1” state, the second layer 22 maintains the high resistance state. Therefore, the sneak current occurring in the cross-point type structure can be suppressed.

In the embodiment, by voltage application, the ionized metal is supplied from the metal layer, so that a conductive filament is formed. At this time, the metal supplied from the first metal layer 11 is likely to be diffused into the second layer 22. Similarly, the metal supplied from the second metal layer 12 is likely to be diffused into the first layer 21. If the diffused metal exists in the first layer 21 or the second layer 22, a difference in retention characteristic between the first layer 21 and the second layer 22 is reduced. In the embodiment, the third layer 30 which suppresses the diffusion of metal is provided between the first layer 21 and the second layer 22. Thereby, it is possible to suppress the diffusion of metal. By using the silicon nitride, the silicon oxynitride, or the silicon oxide for the third layer 30, the effect of diffusion suppression is increased. By using the silicon nitride, the effect of diffusion suppression can be particularly increased.

In the embodiment, the data retention characteristic is based on stability of a conductive filament. For example, the filament formed by the metal supplied from the metal layer is bound with the material contained in the resistance variable layer. If the binding is stable, a good retention characteristic can be obtained. On the other hand, if the binding is unstable, the retention characteristic is bad.

When the resistance variable layer is made of an oxide, the data retention characteristic depends on a binding strength between the metal supplied from the metal layer and the oxygen of the resistance variable layer. In the case where the binding energy with respect to the oxygen is high and a metal having stable binding is used for the metal layer, the retention characteristic is high. On the other hand, in the case where the binding energy with respect to the oxygen is low and a metal having unstable binding is used for the metal layer, the retention characteristic is low. For example, by using metals having different binding energy with respect to the oxygen for two metal layers, different retention characteristics can be obtained.

In the case where the resistance variable layer is made of silicon (for example, polysilicon), the data retention characteristic depends on a binding strength between the metal supplied from the metal layer and the silicon. For example, a metal having high binding energy with respect to the silicon is used for the first metal layer 11, and a metal having low binding energy with respect to the silicon is used for the second metal layer 12.

In the embodiment, two resistance variable layers having different retention characteristics are stacked. Thereby, it is possible to suppress the leak current (sneak current). Accordingly, a stable memory operation can be performed.

### Second Embodiment

A nonvolatile memory device according to the embodiment is a cross-point type memory. In the nonvolatile memory device according to the embodiment, the stacked body 10 described in the first embodiment and modifications thereof are used.

FIG. 4A to FIG. 4D are schematic perspective views illustrating a nonvolatile memory device according to a second embodiment.

As shown in FIG. 4A, in a nonvolatile memory device 121 according to the embodiment, a first metal layer 11 extends in a first direction (X-axis direction). The first direction intersects (in this example, is perpendicular to) a stacking direction (Z-axis direction) from a second layer 22 toward a first layer 21. In addition, the second metal layer 12 extends in a second direction (Y-axis direction). The second direction intersects (in this example, is perpendicular to) the stacking direction. Accordingly, the second direction crosses (in this example, is perpendicular to) the first direction.

When the first layer 21, the second layer 22, and a third layer 30 are projected on a plane (X-Y plane) perpendicular to the stacking direction, the first layer, second layer, and third layer overlap a portion of the first metal layer 11. Accordingly, when the first layer 21, second layer 22, and third layer 30 are projected on the X-Y plane, the first layer, second layer, and third layer overlap with a portion of the second metal layer 12. In the example, the first metal layer 11 becomes one interconnection, and the second metal layer 12 becomes another one interconnection. Accordingly, the first layer 21, second layer 22, and third layer 30 are provided at the position where the interconnections cross each other.

As shown in FIG. 4B, in the nonvolatile memory device 122, a first interconnection 41 is provided. The first interconnection 41 extends in the first direction. The second metal layer 12 extends in the second direction. The first layer 21, the second layer 22, the third layer 30, and the first metal layer 11 are provided between the first interconnection 41 and the second metal layer 12. When the stacked body 10 is projected on the X-Y plane, the stacked body overlaps a portion of the first interconnection 41.

As shown in FIG. 4C, in the nonvolatile memory device 123, a second interconnection 42 is provided. The second interconnection 42 extends in the second direction. The first metal layer 11 extends in the first direction. The first layer 21, the second layer 22, the third layer 30, and the second metal layer 12 are provided between the second wiring 42 and the first metal layer 11. When the stacked body 10 (first layer 21, second layer 22, third layer 30, first metal layer 11, and second metal layer 12) is projected on the X-Y plane, the stacked body 10 overlaps a portion of the second wiring 42.

As shown in FIG. 4D, in the nonvolatile memory device 124, the first interconnection 41 and the second interconnection 42 are provided. The stacked body 10 is disposed between the first interconnection 41 and the second interconnection 42.

In the embodiment, at least one of the first metal layer and the second metal layer 12 may be used as an interconnection. Apart from the first metal layer 11 and the second metal layer 12, an interconnection (at least one of the first interconnection 41 and the second interconnection 42) may be provided.

A stacked film including the first layer 21, the second layer 22, and the third layer 30 may have a prismatic shape or a cylindrical shape (including a flat cylinder shape).

FIG. 5 is a schematic plan view illustrating the nonvolatile memory device according to the second embodiment.

As shown in FIG. 5, in the nonvolatile memory device 125, a plurality of interconnections 61 and a plurality of interconnections 62 are provided. The plurality of the interconnections 61 are parallel to each other. The plurality of the interconnections 62 are parallel to each other. The extending direction of the interconnections 61 crosses the extending direction of the interconnections 62. For the interconnections 61, for example, the first metal layer 11 or the first interconnection 41 are used. For the wirings 62, for example, the second metal layer 12 or the second interconnection 42 are used. The interconnections 61 are used, for example, as word lines. The interconnections 62 are used, for example, as bit lines.

A plurality of stacked bodies 10 (each stacked body including at least the first layer 21, the second layer 22, and the third layer 30) are provided at crossings of the plurality of the interconnections 61 and the plurality of the interconnections 62. The interconnections 61 and the interconnections 62 are connected to a control unit 63 (control circuit). One of the stacked bodies 10 is set to be in the selected state by the interconnection 61 and the interconnections 62, and a desired operation is performed. The nonvolatile memory device 125 is a cross-point type resistance variable memory.

The control unit 63 applies the first pulse to the first metal layer 11 to form the first current path 51. The control unit 63 applies the second pulse to the second metal layer 12 to form the second current path 52.

For example, the control unit 63 (the control circuit) is configured to apply a first potential and a second potential to the first metal layer 11. A first current path 51 is formed in the first layer 11 when the control circuit performs a first operation of applying the first potential to the first metal layer 11. The first potential is positive with respect to the second metal layer 12. A second current path 52 is formed in the second layer 12 when the control circuit performs a second operation of applying the second potential to the first metal layer 11. The second potential is negative with respect to the second metal layer 12. Then, for example, a second time period when the second current path 52 continues to exist after completion of the application of the second potential is shorter than a first time period when the first current path 51 continues to exist after completion of the application of the first potential.

In the nonvolatile memory device 125, a substrate 64 is provided. The interconnections 61 and the interconnections 62 are provided on the substrate 64. The stacking order in the stacked body 10 is arbitrary. For example, the second metal layer 12 may be disposed between the substrate 64 and the first metal layer 11. On the other hand, the first metal layer 11 may be disposed between the substrate 64 and the second metal layer 12. The stacking direction of the stacked body 10 may intersect the major surface of the substrate 64.

A plurality of the stacked bodies 10 may also be stacked. In other words, the embodiment can be applied to a cross-point type memory having a three-dimensional stacked structure.

FIG. 6 is a schematic cross-sectional view illustrating another nonvolatile memory device according to the second embodiment. As shown in FIG. 6, the nonvolatile memory device 126 further includes a third metal layer 11a, a fourth layer 21a, a fifth layer 22a, and a sixth layer 30a in addition to the stacked body 10. In the example, the second metal layer 12 is disposed between the third metal layer 11a and the first metal layer 11. The fourth layer 21a is disposed between the third metal layer 11a and the second metal layer 12. The sixth layer 30a is disposed between the fourth layer 21a and the second metal layer 12. The fifth layer 22a is disposed between the sixth layer 30a and the second metal layer 12.

In the example, the second metal layer 12 has a shape of a strip extending in the Y-axis direction. Insulating layers 12i are provided between a plurality of the second metal layers 12. The first metal layer 11 extends, for example, in the X-axis direction, and the third metal layer 11a extends, for example, in the X-axis direction.

The third metal layer 11a can be applied with the same configuration and the same material as that of the first metal layer 11. The fourth layer 21a can be applied with the same configuration and the same material as that of the first layer 21. The fifth layer 22a can be applied with the same configuration and the same material as that of the second layer 22. The sixth layer 30a can be applied with the same configuration and the same material as that of the third layer 30.

The third metal layer 11a, the fourth layer 21a, the fifth layer 22a, the sixth layer 30a, and the second metal layer 12 forms a second stacked body 10a. The second metal layers 12 are shared by the stacked body 10 and the second stacked body 10a. Due to the sharing, the structure becomes simple. Since some processes can be omitted, it is possible to achieve high productivity. The stacked body 10 functions as one memory component. The second stacked body 10a functions as another one memory component. It is possible to provide a high-density memory device.

According to the embodiment, it is possible to provide a nonvolatile memory device capable of performing stable operations.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in nonvolatile memory devices such as metal layers, first to third layers, interconnects, controllers, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all nonvolatile memory devices practicable by an appropriate design modification by one skilled in the art based on the nonvolatile memory devices described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nonvolatile memory device comprising:
a first metal layer containing at least one first metal selected from the group consisting of Al, Ni, Ti, Co, Mg, Cr, Mn, Zn, and In;
a second metal layer containing at least one second metal selected from the group consisting of Ag, Cu, Fe, Sn, Pb, and Bi;
a first layer provided between the first metal layer and the second metal layer, the first layer containing a first oxide;
a second layer provided between the first layer and the second metal layer, the second layer containing a second oxide; and
a third layer provided between the first layer and the second layer, the third layer containing one of a silicon oxide, a silicon nitride, and a silicon oxynitride.

2. A nonvolatile memory device comprising:
a first metal layer containing at least one first metal selected from the group consisting of Ti, Co, and Cr;
a second metal layer containing at least one second metal selected from the group consisting of Ag, Cu, Al, Ni, Mg, Mn, Fe, Zn, Sn, In, Pb, and Bi;
a first layer provided between the first metal layer and the second metal layer, the first layer containing silicon;
a second layer provided between the first layer and the second metal layer, the second layer containing silicon; and
a third layer provided between the first layer and the second layer, the third layer containing one of a silicon oxide, a silicon nitride, and a silicon oxynitride.

3. A nonvolatile memory device comprising:
a first metal layer containing at least one first metal selected from the group consisting of Ti, Co, and Cr;
a second metal layer containing at least one second metal selected from the group consisting of Ag, Cu, Fe, Sn, Pb, and Bi;
a first layer provided between the first metal layer and the second metal layer, the first layer containing silicon;
a second layer provided between the first layer and the second metal layer, the second layer containing a second oxide; and
a third layer provided between the first layer and the second layer, the third layer containing one of a silicon oxide, a silicon nitride, and a silicon oxynitride.

4. A nonvolatile memory device comprising:
a first metal layer containing at least one first metal selected from the group consisting of Al, Ni, Ti, Co, Mg, Cr, Mn, Zn, and In;
a second metal layer containing at least one second metal selected from the group consisting of Ag, Cu, Al, Ni, Mg, Mn, Fe, Zn, Sn, In, Pb, and Bi;
a first layer provided between the first metal layer and the second metal layer, the first layer containing a first oxide;
a second layer provided between the first layer and the second metal layer, the second layer containing silicon; and
a third layer provided between the first layer and the second layer, the third layer containing one of a silicon oxide, a silicon nitride, and a silicon oxynitride.

5. A nonvolatile memory device comprising:
a first metal layer containing at least one first metal selected from the group consisting of Ag, Cu, Al, Ni, Ti, Co, Mg, Cr, Mn, Fe, Zn, Sn, In, Pb, and Bi;
a second metal layer containing at least one second metal selected from the group consisting of Ag, Cu, Al, Ni, Ti, Co, Mg, Cr, Mn, Fe, Zn, Sn, In, Pb, and Bi, the second metal being different from the first metal;
a first layer provided between the first metal layer and the second metal layer, the first layer containing a first material of one of a first oxide and silicon;
a second layer provided between the first layer and the second metal layer, the second layer containing a second material of one of a second oxide and silicon; and
a third layer provided between the first layer and the second layer, the third layer containing one of a silicon oxide, a silicon nitride, and a silicon oxynitride,
binding energy between the first metal and oxygen being higher than binding energy between the second metal and oxygen when the first material includes the first oxide and the second material includes the second oxide,
the binding energy between the first metal and oxygen being higher than binding energy between the second metal and silicon when the first material includes the first oxide and the second material includes silicon,
binding energy between the first metal and silicon being higher than the binding energy between the second metal and oxygen when the first material includes silicon and the second material includes the second oxide, and
the binding energy between the first metal and silicon being higher than the binding energy between the second metal and silicon when the first material includes silicon and the second material includes silicon.

6. A nonvolatile memory device comprising:
a first metal layer containing a first metal;
a second metal layer containing a second metal, the second metal being different from the first metal;
a first layer provided between the first metal layer and the second metal layer, the first layer containing one of a first oxide and silicon;
a second layer provided between the first layer and the second metal layer, the second layer containing one of a second oxide and silicon;
a third layer provided between the first layer and the second layer, the third layer containing one of a silicon oxide, a silicon nitride, and a silicon oxynitride; and
a control circuit configured to apply a first potential and a second potential to the first metal layer,
a first current path being formed in the first layer when the control circuit performs a first operation of applying the first potential to the first metal layer, the first potential being positive with respect to the second metal layer,
a second current path being formed in the second layer when the control circuit performs a second operation of applying the second potential to the first metal layer, the second potential being negative with respect to the second metal layer, and
a second time period when the second current path continues to exist after completion of the application of the second potential being shorter than a first time period when the first current path continues to exist after completion of the application of the first potential.

7. The device according to claim 6, wherein the second time period is 100 microseconds or less.

8. The device according to claim 1, wherein
a second resistance is higher than a first resistance,
the first resistance is an electric resistance between the first metal layer and the second metal layer after the control circuit applies a first potential to the first metal layer, the first potential being positive with respect to the second metal layer, and
the second resistance is the electric resistance between the first metal layer and the second metal layer after the control circuit applies a second potential to the first metal layer, the second potential being negative with respect to the second metal layer.

9. The device according to claim 8, wherein, the control circuit detects the electric resistance between the first metal layer and the second metal layer by applying a third potential to the first metal layer, the third potential is negative with respect to the second metal layer and has an absolute value smaller than an absolute value of the second potential.

10. The device according to claim 1, wherein
the first metal layer extends in a first direction intersecting a stacking direction from the second layer toward the first layer, and
the first layer, the second layer, and the third layer overlap a portion of the first metal layer when the first layer, the second layer, and the third layer are projected on a plane perpendicular to the stacking direction.

11. The device according to claim 1, wherein
the second metal layer extends in a second direction intersecting a stacking direction from the second layer toward the first layer, and
the first layer, the second layer, and the third layer overlap a portion of the second metal layer when the first layer, the second layer, and the third layer are projected on a plane perpendicular to the stacking direction.

12. The device according to claim 1, wherein
the first metal layer extends in a first direction intersecting a stacking direction from the second layer toward the first layer,
the second metal layer extends in a second direction intersecting the stacking direction, and
the first layer, the second layer, and the third layer overlap an area where the first metal layer and the second metal layer overlap each other when the first layer, the second layer, and the third layer are projected on a plane perpendicular to the stacking direction.

13. The device according to claim 1, further comprising:
a first interconnection extending in a first direction intersecting a stacking direction from the second layer toward the first layer; and
a second interconnection extending in a second direction intersecting the stacking direction,
the first layer, the second layer, the third layer, the first metal layer, and the second metal layer being disposed between the first interconnection and the second interconnection.

14. The device according to claim 1, wherein the first oxide is different from the second oxide.

15. The device according to claim 1, wherein the first oxide is same as the second oxide.

16. The device according to claim 5, wherein
the first layer is a silicon layer, and
the second layer is a silicon layer.

17. The device according to claim 5, wherein
the first layer is a polysilicon layer, and
the second layer is a polysilicon layer.

18. The device according to claim 1, wherein a thickness of the third layer is 1 nanometer or more and 5 nanometers or less.
